(19) United States
(12) Patent Application Publication
(10) Pub. No.: US 2010/0038240 A1
(43) Pub. Date: Feb. 18, 2010

(54) Powder-Fiber Adhesive

(75) Inventors: Christoph Simons, Biebergemund (DE); Martin Schlott, Offenbach (DE); Peter Preissler, Geiselbach (DE); Josef Heindel Josef Heindel, Hainburg (DE)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: W. C. HERAEUS GMBH, Hanau (DE)

(21) Appl. No.: 11/993,686

(22) PCT Filed: Jun. 13, 2006
(86) PCT No.: PCT/EP2006/005652

§ 371 Date: Dec. 21, 2007

(30) Foreign Application Priority Data
Jun. 22, 2005 (DE) 10 2005 029 221.6

(51) Int. Cl. C09J 9/02; B32B 27/20; C23C 14/34; H01B 1/02

(52) U.S. Cl. 204/298.13; 442/149; 204/298.12; 252/500; 252/514; 252/513; 252/515

(57) ABSTRACT

An adhesive is provided, in particular for the adhesion of conductive materials, having at least one binder component and fillers, wherein the fillers contain fibers or a fiber-powder mixture and the fibers and/or powder contain an electrically conductive material. Further, an assembly is provided made of a sputtering target material and a carrier material with an adhesive.

### CROSS-REFERENCE TO RELATED APPLICATION

This application is a Section 371 of International Application No. PCT/EP2006/005652, filed Jun. 13, 2006, which was published in the German language on Dec. 28, 2006, under International Publication No. WO 2006/136310 A3, the disclosure of which is incorporated herein by reference.

### BACKGROUND OF THE INVENTION

The invention relates to an electrically and thermally conductive adhesive, as well as to an assembly made of at least one sputtering target material and a carrier material.

Conductive adhesives are known, for example, from Japanese Published Patent Applications JP 01279986 A, JP 11092727 A, and JP 63066278 A, German Published Patent Application DE 19640192 A1. For mounting microchips, an anisotropic, electrically conductive plastic (anisotropic conductive adhesive=ACA) is used, which is electrically conductive perpendicular to the flip-chip contacting plane and which has an insulating effect in the contacting plane. As electrically conductive particles, metals, for example, are specified, as well as, in particular, sharp-edged ceramic or crystalline particles coated with layers having good conductivity, for example made of graphite. Such particles, however, can contact only substrates having sufficient flatness.

For thin-film coating of substrates, for example in the field of large surface-area coating of window/architectural glass or of monitor screens, foils, among other things, sputtering technology is used. Here, a coating material is connected as a cathode in a sputtering process and atomized and deposited onto the substrate directly or in reaction with a gas as a reaction partner. The layers produced in this way distinguish themselves by a high conformity and layer thickness homogeneity. The coating material is designated as a so-called sputtering target and is provided in solid form, for example as a cylindrical disk or rectangular plate, here one speaks of a flat or planar target.

Usually, this material is fixed on a carrier plate made of, for example copper. The mounting in the sputtering system takes place via this carrier plate. The carrier plate itself is in direct or indirect contact with a coolant, usually water, because the greatest part of the sputtering energy is converted into heat, which in turn is to be led away from the sputtering target material. In addition to the above flat or planar targets, there exist, more and more, tubular or cylindrical targets. Here, the target material is formed into a tube and is generally fixed on a carrier tube made of stainless steel. The dissipation of the sputtering energy occurs by internal cooling of the carrier tube.

With all of these applications the fixing (thermal and electrical connection) of the target material on its carrier (plate or tube) is of great importance, because the method and means of fixing also decisively determines the heat transport from the target material to the carrier. If the target material has a high melting point and is elastic, this fixing can take place by a clamping; if the target material has a low melting point, is very brittle, or is heat insulating, soldering is preferred for fixing, which should guarantee 100% contact between the target material and carrier. In individual cases, adhesives between the target material and carrier are also used. Adhesives have the advantage of being able to be used in the cold state. For the adhesion of a tubular target material on a carrier tube, for example, the problem of different heat expansion between the tubular target material and the carrier tube material is avoided, which occurs during the soldering process and frequently produces an undesired solder gap between the target material and carrier tube or forms cracks, especially when a brittle target material is used. Adhesives can also replace soldering for surfaces that are difficult to wet. In addition, adhesives are usually simple to control in terms of processing. However, these adhesives must be electrically and thermally conductive. Intrinsically conductive adhesives lead to weak properties, usually by orders of magnitude. Therefore, the adhesives in question, for example based on an epoxy resin, are usually filled with metal powders.

It has been shown, however, that the metal-filled adhesives develop electrical conductivity only under application of pressure during adhesion. Here, the metal particles are pushed against each other and thus allow partial metal contact, so that electrical conductivity is produced. With the adhesion of tubular targets, no pressure can be exerted on the adhesive, so that the adhesive generates no or only an extremely weak electrically conductive connection between the target material and the carrier tube. It has also been shown that conventional adhesives are usually offered for small and very small surface area adhesions/spot adhesions and are uneconomically expensive for large surface area applications.

Another problem is the poor wettability of long cylinder tubes, especially for soldering, due to the spatial closeness. Known brittle materials are, for example, ITO (indium-tin oxide) and IZO (indium-zinc oxide), ZnO:Al, and TiO₂ ceramics, Si, and also many alloys with a high content of intermetallic phases. In addition, many transition and refractory metals are difficult to wet.

### BRIEF SUMMARY OF THE INVENTION

An object of the invention is to develop an improved thermally and electrically conductive adhesive, in order to guarantee, among other things, adequate electrical conductivity and heat conductivity between the target material and carrier, even for formation as a tubular target with a carrier tube, especially based on ceramic or other brittle materials, and also based on poorly wettable transition or refractory metals, for manufacture that is simple in terms of processing. In addition, the production of cracks should be prevented.

The adhesive according to the invention, in particular for the adhesion of conductive materials, has at least one binder (bonding agent) component and fillers, wherein the fillers comprise fibers or fiber-powder mixtures and the fibers and/or powders are made of an electrically conductive material. Preferably, the powder and/or the fibers are formed from a material of the group Ag, Au, Al, Cu, Fe, Ni, stainless steel, W, Zn, C, and their alloys. Preferably, the binder component is embedded in a matrix made of fibers or a fiber-powder mixture. The fibers or the fiber-powder mixture can also be embedded in a binder matrix. In particular, the fibers can form a woven fabric, knitted fabric, knotted fabric, or nonwoven fabric. It is further advantageous that the filler, in particular the fibers, have a proportion of 5 to 60 vol.-% of the adhesive. The binder component can be formed based on a monomer or polymer, in particular based on an epoxy compound or an epoxy resin and is preferably curable at temperatures below 100° C. The adhesive has an electrical resistance of less than 100Ω, measured between commercially typical measurement points and geometric conditions of the measurement arrangement according to Example 1.

The assembly according to the invention, made of a sputtering target material and a carrier material, is characterized in that the sputtering target material is adhered onto the carrier material and the adhesive gap is bridged by an adhesive according to the invention. Preferably, the sputtering target material is formed from a material based on Mo, Nb, Cr, W, Ta, Zr, Al, Si, or a ceramic, especially based on tin oxide, zinc oxide, titanium oxide, indium oxide, tantalum oxide, or niobium oxide. In particular, the sputtering target material is formed as at least one sputtering target tube and the carrier material is formed as a carrier tube. The tubes can also be formed as partial tubes.

First tests with conventional metal-filled adhesives on tubular sputtering targets resulted in no reliable, full area contact being produced. In contrast to the adhesion of planar sputtering targets, the necessary pressure is lacking for the cylindrical arrangement of a tubular target, which pressure would press some adhesive out and thus would form many good electrical paths between the sputtering target material and carrier material via the metal particles. For this reason, it was attempted to produce this electrical and thermal connection according to an alternative possibility. Surprisingly, it has been shown that very good results are produced when the intermediate space between the sputtering target tube and the carrier tube is filled with a fleece, a mat, or a fabric made of electrically and thermally conductive material. If the strength of this fiber-based filler material is designed so that this filler material is slightly compressed when pushing the cylinder onto the carrier tube, a reliable electrical and thermal connection is produced in connection with a filling of the hollow spaces by an adhesive, for example, an epoxy resin/elastomer.

The object is achieved according to the invention by an adhesive filled with particles of a powder-fiber mixture of electrically conductive materials. Preferably, the particle mixture is made of metal powder and graphite fibers. In a surprising way, the addition of fibers, especially graphite fibers, permits for the first time a sufficient contacting and bridge formation between the electrically conductive particles.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a schematic diagram for a measurement setup for measuring electrical resistance.

### DETAILED DESCRIPTION OF THE INVENTION

For producing an adhesive, a metal powder-graphite fiber mixture is produced and then stirred into the adhesive. Here, the introduction of air bubbles must be avoided. Stirring under a vacuum is advantageous.

The adhesive can be formed on an organic or inorganic basis. The powder should have a large grain size in the range of 50-250 μm and should be made of an electrically and thermally conductive metal. Here, Al, Ag, Cu, Ni powder have proven effective. The fibers should have fiber lengths greater than 0.2 mm (and less than 0.5 mm) and should constitute a weight percentage of at least 5% in the fiber-powder mixture. The entire fiber-powder mixture should constitute a proportion of at least 40 wt.-% of the total adhesive mass.

### Example 1

100 g of a particle mixture is produced from, e.g., Cu powder (grain size 70-150 μm) with graphite fibers (fiber length 0.3 mm) in a mass ratio of 9:1. The mixture is prepared in an asymmetric mixer. Then, the mixture is carefully stirred into 100 g of an epoxy resin adhesive.

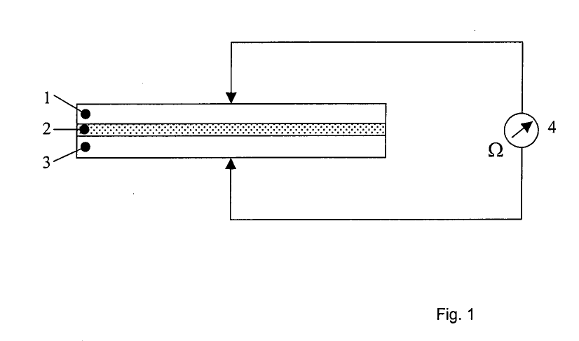

With this adhesive, two 5 mm thick, 10 cm×10 cm (100 cm²) sized copper plates 1; 3 are adhered to each other over their surfaces. The adhesive gap is set at 0.5 mm and filled with the adhesive 2. Then, the electrical resistance is measured in a simple manner with an ohmmeter 4 using commercially typical measurement points (FIG. 1) and compared with resistance values of other adhesives (Table 1).

TABLE 1

| | Measured electrical |
|---|---|
| Adhesive | resistance |
| Non-conductive epoxy resin adhesive | >1 MΩ (not elec- |
| | trically conductive) |
| Epoxy resin adhesive with 50 wt. % Cu powder | ca. 10 kΩ |
| Epoxy resin adhesive according to the invention | 30Ω |

With an adhesive gap of 1 mm and an adhesion surface of 10 cm², a commercially typical conductive adhesive exhibits a resistance greater than 1 MΩ, and the adhesive according to the invention exhibits a resistance of 90Ω.

With an adhesive gap of 0.5 mm and an adhesion surface of 5 cm², a commercially typical conductive adhesive exhibits a resistance of approximately 1 kΩ, an Ag-filled (35 wt. %) epoxy adhesive exhibits a resistance of 150Ω, and the adhesive according to the invention exhibits a resistance of 5Ω. The adhesive according to the invention has significantly better conductivity (lower resistance) than conventional conductive adhesives.

### Example 2

100 g of a particle mixture is produced from, for example, Cu powder (grain size 70-150 μm) with graphite fibers (fiber length 0.3 mm) in a mass ratio of 9:1. The mixture is prepared in an asymmetric mixer. Then, the mixture is carefully stirred into 100 g of an epoxy resin adhesive. The tubular target segment made of, for example, electrically conductive ceramic, such as ITO or ZnO, having a length of 300 mm, an outer diameter of 154 mm, and an inner diameter of 135 mm is now pushed onto the carrier tube having an outer diameter of 133 mm. The resulting bond gap is sealed at one end. Then, in the adhesive mixture prepared above, the hardening agent components are stirred in according to manufacturer information, and the bond gap between the target tube segment and the carrier tube is filled with the adhesive. Here, attention is to be given to slow filling without air bubble inclusions. After filling the bond gap, the system is left alone for hardening.

### Example 3

A stainless steel sleeve having an outer diameter of 133 mm and a length of 700 mm is covered with a 500 mm long knotted Cu hose, which has a wall thickness of ca. 3 mm. The region covered with the hose is coated well with an epoxy resin. Then, a 500-mm long Cr tube having an inner diameter of 136 mm and an outer diameter of 155 mm is pushed onto this region. Before pushing into one another, the Cr tube is also wetted from the inside with epoxy resin. After hardening at approximately 60° C., a connection with good electrical and thermal conductivity is produced.

1-11. (canceled)

12. An adhesive for adhesion of conductive materials, comprising at least one binder component and fillers, wherein the fillers contain fibers or a fiber-powder mixture and the fibers and/or powder comprises an electrically conductive material.

13. The adhesive according to claim 12, wherein the electrically conductive material is selected from the group Ag, Au, Al, Cu, Fe, Ni, stainless steel, W, Zn, C, and their alloys.

14. The adhesive according to claim 12, wherein the binder component is embedded in a matrix made of the fibers or fiber-powder mixture or the fibers or fiber-powder mixture is embedded in the binder matrix.

15. The adhesive according to claim 12, wherein the fillers comprise the fibers in a form of a woven fabric, knitted fabric, knotted fabric, or nonwoven fabric.

16. The adhesive according to claim 12, wherein the fillers comprise the fibers in a proportion of 5 to 60 vol.-% of the adhesive.

17. The adhesive according to claim 12, wherein the binder component is based on a monomer or polymer

18. The adhesive according to claim 12, wherein the binder component is based on an epoxy compound or an epoxy resin.

19. The adhesive according to claim 12, wherein the binder component is curable at temperatures less than 100 C.

20. An assembly comprising a sputtering target material and a carrier material, wherein the sputtering target material is adhered onto the carrier material with an adhesive gap bridged by an adhesive according to claim 12.

21. The assembly according to claim 20, wherein the sputtering target material comprises a material based on Mo, Nb, Cr, W, Ta, Zr, Al, or Si.

22. The assembly according to claim 20, wherein the sputtering target material comprise a ceramic.

23. The assembly according to claim 22, wherein the ceramic is based on tin oxide, zinc oxide, titanium oxide, indium oxide, tantalum oxide, or niobium oxide.

24. The assembly according to claim 20, wherein the sputtering target material has a form of at least one sputtering target tube and the carrier material has a form of a carrier tube.
